(19) United States
(12) Patent Application Publication
(10) Pub. No.: US 2006/0193187 A1
(43) Pub. Date: Aug. 31, 2006

(54) Disk drive unit having reduced electrical power consumption

(75) Inventors: Wouter Harry Jacinth Rensen, Eindhoven (NL); Ralph Kurt, Eindhoven (NL); Michael Adrianus Henricus Van Der AA, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: Koninklijke Philips Electronics N.V., Eindhoven (NL)

(21) Appl. No.: 10/548,847

(22) PCT Filed: Mar. 11, 2004
(86) PCT No.: PCT/IB04/50232

§ 371 Date: Sep. 9, 2005

(30) Foreign Application Priority Data
Mar. 14, 2003 (EP) 03100657.0

(51) Int. Cl. G11C 7/02

(52) U.S. Cl. 365/208

(57) ABSTRACT

A disk drive unit for a disk, e.g. for use in a mobile device, comprises a spindle (1) positioned within the disk drive unit and adapted to support the disk rotatably in an operating position. An electric motor (2) is operatively coupled to the spindle (1) to rotate it. An auxiliary electric motor (3) is connectable to the spindle to accelerate the spindle during start-up. This auxiliary motor can be selected to work efficiently at zero speed. The electric motor may be a low-power motor, resulting in a reduced power consumption.

The invention relates to a disk drive unit for a disk, in particular for use in mobile devices, which disk drive unit comprises a spindle positioned within the disk drive unit and adapted to support the disk rotatably in an operating position, and an electric motor operatively coupled to the spindle so as to rotate the latter.

Disk drive units of this type are known in many embodiments thereof. The electrical power consumption of this kind of disk drives is an important issue, especially if they are used in mobile devices because these mobile devices often suffer from limited power budgets.

U.S. Pat. No. 5,016,124 discloses a recording apparatus with a controlled supply of energy to a disk drive at start-up. In this recording apparatus, there is a disk drive for driving a disk-shaped magnetic tape in order to record a video signal. The electric motor of this disk drive unit has a motor control circuit comprising a first circuit which is arranged to limit a motor driving current to a first value and a second circuit which is arranged to limit the motor driving current to a second value lower than the first value. This way provides a motor control circuit which enables a motor to have a high built-up speed of its rotation when necessary and reduces electric energy consumption when the high built-up speed is not necessary.

It is an object of the present invention to provide a disk drive unit for a disk, wherein the electrical power consumption is further reduced.

In order to accomplish that objective, the invention provides a disk drive unit for a disk, in particular for use in mobile devices, which disk drive unit comprises a spindle positioned within the disk drive unit and adapted to support the disk rotatably in an operating position, an electric motor operatively coupled to the spindle so as to rotate the latter, and an auxiliary motor connectable to the spindle to accelerate the spindle during start-up. The auxiliary motor is preferably an electric motor.

The disk drive unit according to the invention comprises two motors, which can each be selected and designed for their specific purpose. In particular, a conventional rotary electric motor is inefficient at zero speed and has to overcome relatively large bearing frictions at start-up, and therefore this rotary motor consumes a high power during acceleration. According to the invention, an auxiliary motor is used for starting the rotation of the spindle, and thus the electric drive motor is mainly needed for maintaining a selected speed. Less power is required for maintaining a rotary speed, and consequently the electric main drive motor may be designed to have a lower power and therefore a lower power consumption.

A type of motor which is very suitable for starting the spindle rotation is a linear motor, such as an electromagnetic or coil motor. Such a motor is more efficient during start-up of the spindle than a rotary motor. Thus, the electric drive motor and the auxiliary motor complement each other very well.

It is very advantageous if the auxiliary motor is also connectable to the spindle during slow-down of the spindle, while the auxiliary motor is provided with means for absorbing and storing energy from the spindle.

In this way, the kinetic energy of the rotating spindle can be used again, which further reduces the electrical power consumption of the disk drive unit. The means for absorbing and storing the energy from the spindle may be electrical, as defined in claim 5, or may be mechanical, as claimed in claim 6. Alternative means for absorbing and storing the energy are obviously conceivable.

One way of connecting the linear motor and the spindle is defined in claim 7. This is a simple way of converting a linear movement into a circular movement.

In the embodiment of claim 8, the plunger takes a central position with respect to the spindle, and the head shape of the plunger and the elastic fixture are very simple means for moving the plunger away from and back to this central position.

This embodiment is also very well suited for use in an embodiment of the disk drive unit wherein the plunger is also used for absorbing and storing the kinetic energy from the spindle during slow-down. Such an embodiment is defined in claim 9. According to this embodiment, the head of the plunger is enabled to move along two sides of the spindle in order to drive the spindle and be driven by the spindle. This embodiment has the additional advantage that it is not necessary anymore to brake the spindle, which would normally require energy. According to the invention, the auxiliary motor brakes the spindle and at the same time stores the energy from the spindle for later use.

The invention also relates to a mobile device having a housing comprising the disk drive unit as described above, and it also includes a method of driving a spindle of a disk drive unit as defined in claims 12 and 13.

These and other aspects of the invention will become apparent from and be elucidated with reference to the embodiment(s) described hereinafter.

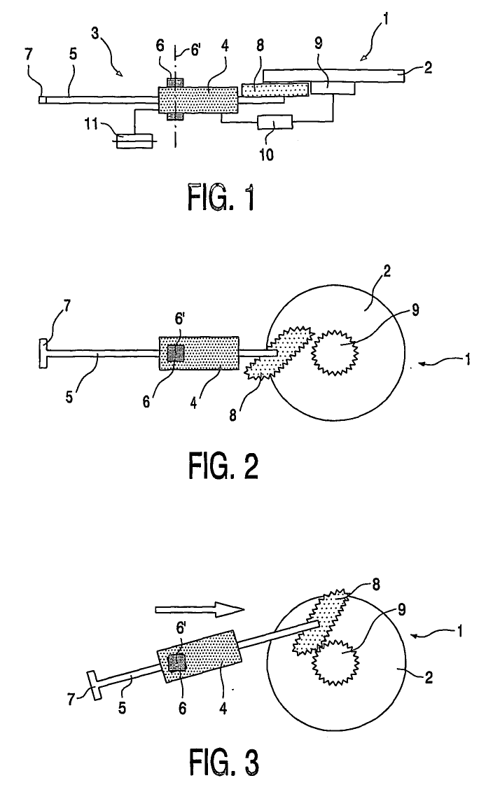

FIG. 1 is a very schematic side view of an embodiment of the disk drive unit according to the invention.

FIGS. 2-6 are very schematic plan views of the embodiment of the disk drive unit according to FIG. 1, in five different positions during operation thereof.

The drawings show an embodiment of a disk drive unit. This disk drive unit may be used in a device for reading and/or writing data from or on a disk (not shown), such as an optical disk or the like. The device in which this disk drive unit is used is particularly a mobile or portable device, for example a mobile phone which is provided with an exchangeable optical data disk. The disk may be accommodated in a cartridge. The mobile device will have a housing in which the disk drive unit is accommodated. The housing will be provided with an opening allowing insertion of the disk from an insertion position into an operating position at a spindle of the disk drive unit and ejection of the disk from the operating position into a released position.

In one particular application of the disk drive unit, the unit is designed to drive very small disks (for example having a diameter of 30 mm). Such a disk drive unit may operate, for example, in a so-called burst mode, which saves energy in comparison with continuous operation. Data is read from the disk at an effective high rate of e.g. 33 Mbit/s and placed in a buffer of typically 8 MB. For example, the data user rate for a certain application is 1 Mbit/s and the acceleration of the disk takes 1 second. This acceleration causes strong energy losses due to static and dynamic friction (bearing friction and air friction), inertia of the disk and the motor, and adaptation of the electrical phase of the electric motor. After acceleration, the power dissipation of the drive unit reduces typically by a factor of 10. In this constant-speed phase, the buffer is filled with data in about 2 seconds. Then, the motor can be stopped and data can be read from the buffer during approximately 1 minute. If the disk contains 1 hour of music, the disk needs to be accelerated about 50 times during playing of this disk.

FIGS. 1-6 very schematically show a disk drive unit according to the invention. It shows a spindle 1 which includes a turntable to support the disk, a shaft to rotate the turntable, and a rotor 2, which is the rotary part of an electric drive motor of the disk drive unit. Any conventional or non-conventional rotary motor may be used.

The drawings also show an auxiliary motor 3 which is connectable to the spindle 1. The auxiliary motor comprises a coil 4 through which an electric current may be conducted, controlled by a control unit 10 which also controls the operation of the electric rotary motor. A magnetized plunger 5 extends through the coil 4 in order to be driven in a linear fashion upon actuation of the coil 4. The coil is mounted to an elastic fixture 6 enabling the coil 4 and plunger 5 to rotate against a biasing force about an axis 6′ substantially perpendicularly to the longitudinal axis of the plunger 5. The biasing force urges the plunger 5 back into a central position in which the longitudinal axis of the plunger 5 extends through the axis of the spindle 1. Other central positions are conceivable.

At one end remote from the spindle 1, the plunger 5 comprises a stop 7 limiting the movement of the plunger 5 in one direction. At the other end, the plunger 5 comprises a toothed head 8 adapted to come into engagement with a toothed wheel 9 on the spindle 1. The toothed head 8 is more or less checker-shaped with rounded corners. The teeth of the toothing are distributed along the entire circumference of the toothed head 8 and are adapted to the teeth of the toothed wheel 9. The wheel 9 may be a gear wheel, a friction wheel, or some other type of wheel enabling the plunger head to exert a driving force on the wheel 9 such that a linear motion of the plunger is transformed into a rotary motion of the spindle 1. The plunger 5, the toothed head 8, and the toothed wheel 9 act as connection members between the auxiliary motor 3 and the spindle 1.

The operation of the disk drive unit as shown and described is as follows.

In FIG. 2 the spindle 1 and a disk supported thereon are at rest. The plunger 5 is in a central rest position, such that its longitudinal axis extends through the axis of the spindle 1 and such that the toothed head 8 is out of engagement with the toothed wheel 9 on the spindle 1. Consequently, the auxiliary motor 3 is disconnected from the spindle 1.

In FIG. 3, the control unit 10 has received a command that the disk should be rotated, so that the spindle 1 needs to start up. For this purpose, the control unit activates the coil 4 by causing a current to run trough the coil 4. The magnetic field created thereby causes the plunger 5 to be forced towards the spindle 1. As a result, the toothed head 8 comes into engagement with the toothed wheel 9 on the spindle 1. Due to the force on the plunger 5 and the orientation of the side of the toothed head 8 that comes into engagement with the toothed wheel 9, the plunger 5 makes a combined linear and rotational movement, in which the coil 4 and the plunger 5 contained therein rotate about the axis 6′ of the elastic fixture 6. As a result of this movement, the toothed head 8 brings the toothed wheel 9 into rotation and simultaneously, the toothed head 8 runs over the circumference of the wheel 9. Due to the acceleration of the spindle 1, the disk supported thereon is accelerated as well.

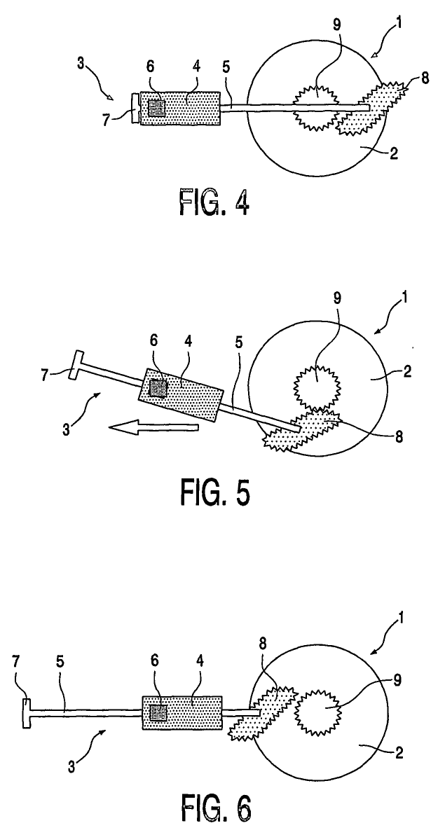

In FIG. 4, the plunger 5 has been moved to its extreme position in which the stop 7 is blocked. When the plunger has reached this position with respect to the coil 4, the toothed head 8 has passed beyond the toothed wheel 9 and has come out of engagement with this wheel 9 on the other side of the spindle 1. The elastic fixture 6 has maintained a return force on the plunger 5, so that the toothed head 8 has been kept in engagement with the toothed wheel 9 and the plunger 5 has been returned to its central position in which a longitudinal axis of the plunger 5 extends through the axis of the spindle 1. In this position, the coil 4 is deactivated and the plunger 5 will remain in this position, or will be actively locked in this position. During the motion of the toothed head 8 around the toothed wheel 9 of the spindle 1, the spindle 1 has been accelerated to a sufficient extent, so that the rotary motor can take over and can bring the spindle to or keep the spindle 1 at the rotary speed that is desired.

When the disk is to be stopped again and the disk therefore needs to be decelerated, the rotary motor of the disk drive unit will be deactivated and the control unit 10 will cause a short reverse current pulse to activate the coil 4. This reverse current pulse will cause a magnetic field in opposite direction, so that the plunger 5 is moved in opposite direction. The pulse is just sufficient to bring the toothed head 8 of the plunger 5 into engagement with the toothed wheel 9 on the spindle 1. Once the toothed head 8 is in engagement with the rotating toothed wheel 9, the inertia of the spindle 1 and the disk will drive the toothed head 8 and will push the plunger 5 back into the coil 4. The elastic fixture 6 will keep the toothed head 8 again in engagement with the toothed wheel 9.

During this process, the mechanical kinetic energy in the spindle 1 and the disk is converted to electric energy in the coil 4, where a current is generated. This energy may be stored in, for example, a capacitor 11 for a later restart of the spindle 1. Another option is to store the energy in a spring (not shown) that is connected to the plunger 5, which acts as a means for transmitting the energy to the means for absorbing and storing the energy.

When the toothed head 8 has come out of engagement with the toothed wheel 9, another short reverse current pulse through the coil 4 disconnects the toothed head 8 of the plunger 5 from the toothed wheel 9, so that the plunger 5 is back in its original position where it is locked.

FIG. 6 shows this original position of the plunger 5 where it is ready for the next acceleration. During this next acceleration both the energy from the coil 4 and the energy from the capacitor and/or spring or other energy storing means is used to drive the plunger 5.

From the above it will be clear that the invention provides a disk drive unit which has a very low energy consumption.

The invention is not limited to the embodiments shown in the drawing and described above, and may be varied in different ways within the scope of the appended claims. Features of the various embodiments described may be combined, while specific features may be replaced by alternatives. For example, the auxiliary motor may also be a rotating electromagnetic motor or the like.

In the specification and claims, the use of the expressions “a” or “an” does not exclude a plurality thereof, while the expression “comprising” does not exclude additional elements or steps. A single processor or unit may fulfil the functions of several means recited in the claims.

In the presently preferred embodiments, the disk is an optical data disk. However, it should be understood that the invention may be used for all kinds of disks, e.g. ferro-electric, magnetic, magneto-optical, optical, near-field, active charge storage disks, or other disks using combinations of these techniques or other reading and/or writing techniques.

1. A disk drive unit for a disk, which disk drive unit comprises a spindle (1) positioned within the disk drive unit and adapted to support the disk rotatably in an operating position, an electric motor (2) operatively coupled to the spindle (1) so as to rotate the latter, and an auxiliary motor (3) connectable to the spindle to accelerate the spindle during start-up.

2. A disk drive unit according to claim 1, wherein the auxiliary motor (3) is an electric motor.

3. A disk drive unit according to claim 2, wherein the auxiliary motor (3) is also connectable to the spindle (1) during slow-down of the spindle, while the auxiliary motor is provided with means (4, 11) for absorbing and storing energy from the spindle (1).

4. A disk drive unit according to claim 3, wherein the linear motor (3) is adapted to be actuated in one direction to drive the spindle (1) during start-up, and the linear motor (3) is also adapted to be actuated in an opposite direction in order to be driven by the spindle (1) during slow-down.

5. A disk drive unit according to claim 3, wherein the means for absorbing the energy comprises the coil (4) of the linear motor (3) and the means for storing the energy comprises a capacitor (11).

6. A disk drive unit according to claim 3, wherein the means for absorbing and storing the energy comprises a spring connected to a moving part (5) of the linear motor (3).

7. A disk drive unit according to claim 2, wherein the auxiliary motor (3) comprises a plunger (5) equipped with a head (8), whilst the spindle (1) comprises a wheel (9) which can be engaged by the head of the auxiliary motor plunger, the plunger (5), the head (8) and wheel (9) acting as connection members between the auxiliary motor (3) and the spindle (1).

8. A disk drive unit according to claim 7, wherein the auxiliary motor (3) is rotatable about an axis (6′) extending substantially perpendicularly to the longitudinal axis of the plunger (5) in order to allow the plunger head (8) to move around the spindle wheel (9), the head of the plunger being shaped such that a rectilinear movement of the plunger head in a central position towards and into engagement with the spindle wheel causes a movement of the plunger head around the spindle (1), thereby bringing it into rotation, the auxiliary motor being provided with an elastic fixture (6) that biases the plunger towards the central position.

9. A disk drive unit according to claim 5, wherein the plunger head (8) is also the means for transmitting the energy from the spindle during its slow-down to the absorbing means (4) by engaging with the wheel (9) of the spindle (1), starting from its central position after start-up of the spindle, wherein a control means (10) of the drive unit is adapted to actuate the auxiliary motor (3) by a reverse current pulse such that the plunger head (8) is pulled back to its starting position and the plunger head is caused to come into engagement with the spindle wheel (9) after the electric motor (2) has been deactivated, thereby bringing the plunger (5) back into its starting position.

10. A disk drive unit according to claim 8, wherein the coil (4) of the auxiliary motor (3) is provided with said elastic fixture (6).

11. Mobile device having a housing comprising the disk drive unit according to claim 1.

12. Method of driving a spindle of a disk drive unit, comprising the following steps in a desired sequence in order to bring the spindle into rotation:
actuating an auxiliary electric motor so as to connect it operatively to the spindle in order to accelerate the latter,
disconnecting the auxiliary electric motor from the spindle and actuating a main electric motor to keep the spindle at a desired rotational speed.

13. The method of claim 12, comprising the following steps in a desired sequence in order to stop rotation of the spindle:
deactivating the main electric motor,
actuating the auxiliary electric motor so as to connect it operatively to the spindle in order to transmit kinetic energy from the spindle to a means for absorbing and storing the kinetic energy of the spindle.
